(19) United States
(12) Patent Application Publication
(10) Pub. No.: US 2025/0308966 A1
(43) Pub. Date: Oct. 2, 2025

(54) WAFER PROCESSING DEVICE, WAFER PROCESSING METHOD, AND ION IMPLANTER

(71) Applicant: Sumitomo Heavy Industries Ion Technology Co., Ltd., Tokyo (JP)

(72) Inventor: Tetsuya KUDO, Ehime (JP)

(21) Appl. No.: 19/237,170

(22) Filed: Jun. 13, 2025

Related U.S. Application Data
(63) Continuation of application No. PCT/JP2023/041225, filed on Nov. 16, 2023.

(30) Foreign Application Priority Data
Dec. 23, 2022 (JP) 2022-207554

(51) Int. Cl. H01L 21/68; B65G 47/90; C23C 14/48; C23C 14/54

(52) U.S. Cl. CPC H01L 21/681; B65G 47/905; C23C 14/48; C23C 14/54

(57) ABSTRACT

A wafer processing device includes a first imaging device that images a wafer which is a processing target, a processing chamber that provides a space for processing the wafer and that includes a wafer holding device configured to hold the wafer inside the processing chamber, a wafer transport device that transports the wafer into the processing chamber and that disposes the wafer on the wafer holding device, one or a plurality of processors, and one or a plurality of memories in which a program executable by the one or the plurality of processors is stored.

### CROSS-REFERENCE TO RELATED APPLICATIONS

This is a bypass continuation of International PCT Application No. PCT/JP2023/041225, filed on Nov. 16, 2023, which claims priority to Japanese Patent Application No. 2022-207554, filed on Dec. 23, 2022, which are incorporated by reference herein in their entirety.

### BACKGROUND

### Technical Field

Certain embodiments of the present invention relate to a wafer processing device and the like.

### Description of Related Art

A wafer transport device including an aligner is disclosed in the related art. The aligner detects an alignment mark (sign) such as a notch and an orientation flat provided in a peripheral edge portion of a wafer with a sensor and rotates the wafer such that the alignment mark comes at a desired rotation position (rotation angle).

### SUMMARY

According to an aspect of the present invention, there is provided a wafer processing device including a first imaging device that images a wafer which is a processing target, a processing chamber that provides a space for processing the wafer and that includes a wafer holding device configured to hold the wafer inside the processing chamber, a wafer transport device that transports the wafer into the processing chamber and that disposes the wafer on the wafer holding device, one or a plurality of processors, and one or a plurality of memories in which a program executable by the one or the plurality of processors is stored. The program includes the following steps of (a) to (c): (a) imaging the wafer with the first imaging device, (b) acquiring first disposition information of the wafer based on a captured image, and (c) transporting the wafer into the processing chamber and disposing the wafer on the wafer holding device with the wafer transport device in a state of being associated with the first disposition information.

According to this aspect, the first disposition information that can be used in alignment of the wafer can be acquired based on the image captured by the first imaging device.

According to another aspect of the present invention, there is provided a wafer processing method. The method in a wafer processing device including a first imaging device that images a wafer which is a processing target, a processing chamber that provides a space for processing the wafer and that includes a wafer holding device configured to hold the wafer inside the processing chamber, and a wafer transport device that transports the wafer into the processing chamber and that disposes the wafer on the wafer holding device, includes (a) a step of imaging the wafer with the first imaging device, (b) a step of acquiring first disposition information of the wafer based on a captured image, and (c) a step of transporting the wafer into the processing chamber and disposing the wafer on the wafer holding device with the wafer transport device in a state of being associated with the first disposition information.

According to still another aspect of the present invention, there is provided an ion implanter. The device includes a first imaging device that images a wafer which is an ion implantation processing target, a processing chamber that provides a space for performing ion implantation processing on the wafer and that includes a wafer holding device configured to hold the wafer inside the processing chamber, a wafer transport device that transports the wafer into the processing chamber and that disposes the wafer on the wafer holding device, one or a plurality of processors, and one or a plurality of memories in which a program executable by the one or the plurality of processors is stored. The program includes the following steps of (a) to (c): (a) imaging the wafer with the first imaging device, (b) acquiring first disposition information of the wafer based on a captured image, and (c) transporting the wafer into the processing chamber and disposing the wafer on the wafer holding device with the wafer transport device in a state of being associated with the first disposition information.

Any combination of the components described above and substitutions of expressions of the present invention between methods, devices, systems, recording media, computer programs, and the like are also effective as aspects of the present invention.

According to an aspect of the present invention, the wafer can be aligned with a simple configuration.

### BRIEF DESCRIPTION OF THE DRAWINGS

FIG. 1 is a top view showing a schematic configuration of an ion implanter.

FIG. 2 is a side view showing the schematic configuration of the ion implanter.

FIG. 3 is a top view showing a schematic configuration of a wafer transport device.

FIG. 4 schematically shows a swap operation by an intermediate transport mechanism.

FIG. 5 schematically shows the swap operation by the intermediate transport mechanism.

FIG. 6 schematically shows the swap operation by the intermediate transport mechanism.

FIG. 7 schematically shows the swap operation by the intermediate transport mechanism.

FIG. 8 is a functional block diagram of the ion implanter.

FIG. 9 schematically shows an example in which a first imaging device simultaneously images a plurality of wafers for alignment of the wafers.

FIG. 10 schematically shows a wafer group imaged by the first imaging device in side view.

FIG. 11 schematically shows a disposition example of a camera around a wafer placing portion in top view.

FIG. 12 schematically shows a disposition example of the camera around the wafer placing portion in top view.

FIG. 13 schematically shows a disposition example of the camera around the wafer placing portion in top view.

FIG. 14 schematically shows a disposition example of the camera around the wafer placing portion in top view.

FIG. 15 is a flowchart showing an example of a program executable by a processor.

FIG. 16 is a flowchart showing an example of the program executable by the processor.

FIG. 17 is a flowchart showing an example of the program executable by the processor.

### DETAILED DESCRIPTION

In the related art, it is necessary to provide a dedicated aligner for alignment of the wafer in a wafer transport device.

The present invention has been devised in view of such circumstances, and it is desirable to provide a wafer processing device and the like capable of aligning a wafer with a simple configuration.

Hereinafter, an embodiment for carrying out the present invention will be described in detail with reference to the drawings. In the description or drawings, the same or equivalent components, members, and processing will be assigned with the same reference numerals, and redundant description thereof will be omitted. The scales and shapes of shown units are set for convenience in order to make the description easy to understand and are not to be understood as limiting unless stated otherwise. The embodiment is merely an example and does not limit the scope of the present invention. All features described in the embodiment and combinations thereof are not necessarily essential to the present invention.

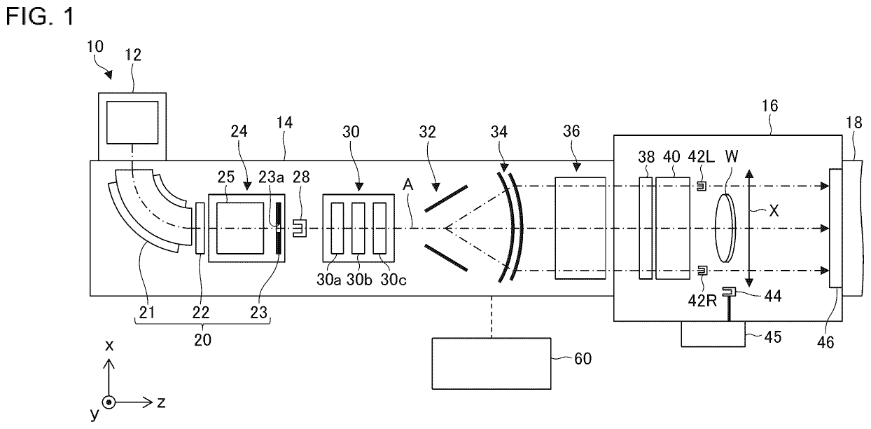

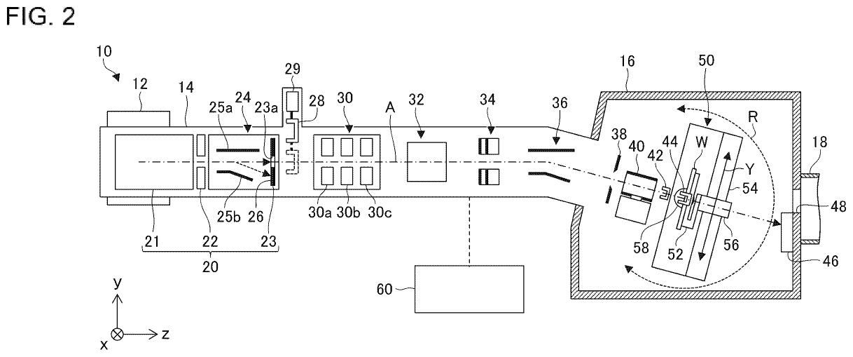

FIG. 1 is a top view showing a schematic configuration of an ion implanter 10 according to the embodiment of the present invention, and FIG. 2 is a side view showing the schematic configuration of the ion implanter 10. The ion implanter 10 is a device that performs ion implantation processing on a surface of a workpiece W. The workpiece W is, for example, a substrate such as a semiconductor wafer and a display device. In the present specification, the workpiece W will also be referred to as a wafer W for convenience. However, a target of the ion implantation processing is not intended to be limited to a specific object or a specific material such as a semiconductor wafer.

The ion implanter 10 can irradiate the entire surface to be processed of the wafer W with an ion beam by performing reciprocating scanning with the ion beam in one direction (hereinafter, also referred to as a scanning direction, a beam scanning direction, and a beam movement direction) and reciprocating the wafer W in a direction perpendicular to the scanning direction (hereinafter, also referred to as a reciprocating direction, a reciprocating movement direction, and a wafer movement direction). In the present specification, a traveling direction (hereinafter, also referred to as a beam traveling direction) of an ion beam traveling along a designed beamline A will be defined as a z-direction, and a plane perpendicular to the z-direction will be defined as an xy-plane. A scanning direction of an ion beam (beam movement direction) in a case where the workpiece W is scanned with the ion beam will be defined as an x-direction, and a y-direction perpendicular to the z-direction and the x-direction will be defined as the wafer movement direction. As described above, the reciprocating scanning with the ion beam is performed in the x-direction, and the reciprocating of the wafer W is performed in the y-direction.

The ion implanter 10 includes an ion generation device 12, a beamline unit 14, an implantation processing chamber 16, and a wafer transport device 18. The ion generation device 12 supplies an ion beam to the beamline unit 14. The beamline unit 14 transports the ion beam supplied from the ion generation device 12 to the implantation processing chamber 16. The wafer W, which is an ion implantation target, is accommodated in the implantation processing chamber 16, and ion implantation processing of irradiating the wafer W with the ion beam supplied from the beamline unit 14 is performed. The wafer transport device 18, which is a transport device, transports an unprocessed wafer before ion implantation processing into the implantation processing chamber 16 so that the wafer is disposed at the wafer holding device 52 and transports a processed wafer after the ion implantation processing out of the implantation processing chamber 16. Although not shown, a vacuum evacuation system for providing a desired vacuum environment to the ion generation device 12, the beamline unit 14, the implantation processing chamber 16, and the wafer transport device 18 is provided in the ion implanter 10.

The beamline unit 14 includes a mass analyzing unit 20, a beam park device 24, a beam shaping unit 30, a beam scan unit 32, a beam parallelizing unit 34, and an angular energy filter (AEF) 36, in order from an upstream side of the beamline A. The upstream (side) of the beamline A is a side close to the ion generation device 12, and a downstream (side) of the beamline A is a side close to the implantation processing chamber 16 (or a beam stopper 46).

The mass analyzing unit 20 provided downstream of the ion generation device 12 selects or extracts a desired ion species used in ion implantation processing from ion beams generated by the ion generation device 12 through mass analysis. The mass analyzing unit 20 has a mass analyzing magnet 21, a mass analyzing lens 22, and a mass resolving aperture 23.

The mass analyzing magnet 21 applies a magnetic field to an ion beam extracted from the ion generation device 12 to deflect the ion beam along a different trajectory according to a value of a mass-to-charge ratio M=m/q (m is mass, and q is charge) of ions. For example, the mass analyzing magnet 21 applies a magnetic field in a −y-direction to the ion beam to deflect the ion beam in the x-direction perpendicular to the beam traveling direction (z-direction). A magnetic field intensity of the mass analyzing magnet 21 is adjusted such that ion species having the desired mass-to-charge ratio M can pass through the downstream mass resolving aperture 23.

The mass analyzing lens 22 is provided downstream of the mass analyzing magnet 21 (and upstream of the mass resolving aperture 23) and adjusts a focusing force/defocusing force (or a focusing degree/divergence degree of an ion beam) with respect to the ion beam. The mass analyzing lens 22 adjusts a focusing position of the ion beam passing through the mass resolving aperture 23 in the beam traveling direction (z-direction) and adjusts a mass resolution M/dM of the mass analyzing unit 20. The mass analyzing lens 22 may not be provided in the mass analyzing unit 20.

The mass resolving aperture 23 is provided at a position separated downstream from the mass analyzing lens 22. The mass resolving aperture 23 includes a rectangular opening 23a having a relatively short width in the x-direction and a relatively long height in the y-direction. Since a width direction (x-direction) of the opening 23a matches a beam deflection direction (x-direction) for the mass analyzing magnet 21, the width (a dimension in the x-direction) of the opening 23a mainly contributes to selection of the desired ion species according to the mass-to-charge ratio M in the mass resolving aperture 23.

The mass resolving aperture 23 may have a variable aperture width (the width of the opening 23a in the x-direction) for adjusting the mass resolution. For example, the mass resolving aperture 23 may be configured by two shield members that are movable relative to each other in an aperture width direction (x-direction), and the aperture width may be adjusted by changing an interval between the two shield members in the aperture width direction. In addition, the mass resolving aperture 23 may change the aperture width by switching a plurality of apertures having different aperture widths.

The beam park device 24 constitutes a beam deflection device that deflects an ion beam with at least one of an electric field and a magnetic field. Specifically, the beam park device 24 is switchable between an irradiation-enabled state where the ion beam is directed in an irradiation-enabled direction in which the wafer W can be irradiated with the ion beam and an irradiation-disabled state where the ion beam is directed in an irradiation-disabled direction in which the wafer W cannot be irradiated with the ion beam. In the example of FIG. 2, an arrow pointing toward an inside of the opening 23a of the mass resolving aperture 23 represents the irradiation-enabled direction, and an arrow pointing toward a beam dump 26 outside the opening 23a of the mass resolving aperture 23 represents the irradiation-disabled direction. Herein, the mass resolving aperture 23 is an aperture through which at least a part of the ion beam directed in the irradiation-enabled direction passes and is provided between the beam park device 24 which is the beam deflection device and a wafer holding device 52 (FIG. 2) which is a workpiece holding device to be described later.

The beam park device 24 in the irradiation-disabled state temporarily retracts an ion beam from the beamline A and shields the ion beam directed toward the downstream implantation processing chamber 16 (or the wafer W) with the beam dump 26. That is, the ion beam directed toward the irradiation-disabled direction collides with the beam dump 26 outside the opening 23a of the mass resolving aperture 23 and is blocked. The beam park device 24 can be disposed at any position on the beamline A, but is disposed between the mass analyzing lens 22 and the mass resolving aperture 23 in the example shown. Since a certain distance or more is required between the mass analyzing lens 22 and the mass resolving aperture 23 as described above, a space can be efficiently used by disposing the beam park device 24 therebetween. As a result, the size of the entire ion implanter 10 can be reduced by shortening the beamline A compared to a case where the beam park device 24 is disposed at another place.

The beam park device 24 shown in FIGS. 1 and 2 constitutes a beam deflection device of a type in which an ion beam is deflected by an electric field. The beam park device 24 includes a pair of park electrodes 25 (25a and 25b) and the beam dump 26. The pair of park electrodes 25a and 25b face each other in the y-direction with the beamline A interposed therebetween. The beam park device 24 switches an irradiation direction of the ion beam between the irradiation-enabled direction and the irradiation-disabled direction according to a change in an electric field in the y-direction caused by a change in a voltage applied between the pair of park electrodes 25a and 25b.

In the example of FIG. 2, when a voltage is not applied between the pair of park electrodes 25a and 25b (that is, when the voltage is substantially zero), a beam of a desired ion species to be used in ion implantation processing is not deflected, and the irradiation-enabled state is obtained in which the beam passes straight through the opening 23a of the mass resolving aperture 23 in the irradiation-enabled direction. On the other hand, when a voltage is applied between the pair of park electrodes 25a and 25b (that is, when a voltage has a significant non-zero value), a beam of the desired ion species to be used in ion implantation processing is deflected in the −y-direction, and the irradiation-disabled state is obtained in which the beam is shielded by colliding with the beam dump 26 outside the opening 23a of the mass resolving aperture 23 in the irradiation-disabled direction.

In the above example, an ion beam travels in the irradiation-enabled direction during non-deflection of an ion beam when a voltage is not applied between the pair of park electrodes 25a and 25b, and the ion beam travels in the irradiation-disabled direction during deflection of an ion beam when a voltage is applied between the pair of park electrodes 25a and 25b, but the ion beam during non-deflection may travel in the irradiation-disabled direction, and the ion beam during deflection may travel in the irradiation-enabled direction. In this case, for example, it is sufficient that the beam dump 26 is provided at the position of the opening 23a of the mass resolving aperture 23 in FIG. 2, and the opening 23a of the mass resolving aperture 23 may be provided at the position of the beam dump 26 in FIG. 2. In this case, a configuration downstream of the opening 23a is also provided on the beamline A of the (deflected) ion beam passing through the opening 23a.

In addition, an ion beam traveling in the irradiation-enabled direction and an ion beam traveling in the irradiation-disabled direction may be deflected by different voltages applied between the pair of park electrodes 25a and 25b. For example, in a case where the irradiation-enabled direction (a direction in which the opening 23a of the mass resolving aperture 23 is positioned) forms a first deflection angle θ1 with respect to a direction in which the ion beam is incident into the beam park device 24 and the irradiation-disabled direction (a direction in which the beam dump 26 is positioned) forms a second deflection angle θ2 significantly different from the first deflection angle θ1 with respect to the direction in which the ion beam is incident into the beam park device 24, a direction in which a beam of a desired ion species travels is switched between the irradiation-enabled direction and the irradiation-disabled direction by switching a voltage applied between the pair of park electrodes 25a and 25b between a first voltage V1 for realizing the first deflection angle θ1 and a second voltage V2 (≠V1) for realizing the second deflection angle θ2.

As described above, a facing direction of the pair of park electrodes 25a and 25b is the y-direction and is perpendicular to the beam deflection direction (x-direction) of the mass analyzing magnet 21. For this reason, a deflection voltage in the y-direction, which is applied between the pair of park electrodes 25a and 25b, does not hinder selection of a desired ion species according to the mass-to-charge ratio M performed by the mass analyzing magnet 21 along the x-direction.

In the example of FIG. 2, the first park electrode 25a is disposed above the beamline A in the gravity-direction (the facing direction of the first park electrode 25a and the second park electrode 25b), and the second park electrode 25b is disposed below the beamline A in the gravity-direction. The beam dump 26 provided downstream of the first park electrode 25a and the second park electrode 25b is disposed below the beamline A in the gravity-direction and below the opening 23a of the mass resolving aperture 23 in the gravity-direction. The beam dump 26 is, for example, a wall-shaped portion in which the opening 23a of the mass resolving aperture 23 is not formed. The beam dump 26 may be configured separately from the mass resolving aperture 23.

An injector Faraday cup 28 that also functions as a beam blocking mechanism is provided downstream of the mass resolving aperture 23. The injector Faraday cup 28 can be inserted into and removed from the beamline A by an operation of an injector drive unit 29. The injector drive unit 29 moves the injector Faraday cup 28 in a direction (for example, the y-direction) perpendicular to a direction in which the beamline A extends (z-direction). As shown by a broken line in FIG. 2, in a case where the injector Faraday cup 28 is disposed on the beamline A, an ion beam directed toward the downstream side is physically blocked, and thus a blocked state is obtained. On the other hand, as shown by a solid line in FIG. 2, in a case where the injector Faraday cup 28 is removed from the beamline A, a non-blocked state is obtained in which the ion beam directed toward the downstream side passes without being physically blocked. As described above, the injector Faraday cup 28 and the injector drive unit 29 function as the beam blocking mechanism switchable between the blocked state in which the ion beam is physically blocked and the non-blocked state in which the ion beam is caused to pass.

The injector Faraday cup 28 measures a beam current of an ion beam mass-analyzed by the mass analyzing unit 20. The injector Faraday cup 28 can acquire a mass-analyzed spectrum of the ion beam by measuring the beam current while changing a magnetic field intensity of the mass analyzing magnet 21. For example, the mass-analyzed spectrum is used in calculating mass resolution of the mass analyzing unit 20.

The beam shaping unit 30 includes a focusing/defocusing device, such as a focusing/defocusing quadrupole lens (Q lens), and shapes an ion beam that has passed through the mass analyzing unit 20 to have a desired cross-sectional shape. For example, the beam shaping unit 30 configured by an electric field type three-stage quadrupole lens (also referred to as a triplet Q lens) includes three quadrupole lenses 30a, 30b, and 30c. By using the three quadrupole lenses 30a to 30c, the beam shaping unit 30 can independently adjust focusing or defocusing of the ion beam in the x-direction and the y-direction. The beam shaping unit 30 may include a magnetic field type lens device or may include a lens device that shapes the ion beam by using both an electric field and a magnetic field.

The beam scan unit 32 performs reciprocating scanning in a predetermined scanning angle range in the x-direction with an ion beam (a beam shaped by the beam shaping unit 30) with which the wafer W is irradiated by at least one of an electric field and a magnetic field. The beam scan unit 32 can also be used as a beam deflection device that deflects the ion beam between the irradiation-enabled direction and the irradiation-disabled direction, instead of or in addition to the beam park device 24. The beam scan unit 32 includes a pair of scanning electrodes facing each other in the beam scanning direction (x-direction). The pair of scanning electrodes are connected to a variable voltage power supply (not shown) and periodically change a voltage applied between the pair of scanning electrodes to change an electric field between the electrodes and to deflect the ion beam at various angles in a zx-plane. As a result, the ion beam is used in scanning over the entire scanning range in the x-direction. In FIG. 1, the scanning direction and the scanning range of the ion beam are shown by an arrow X, and a plurality of trajectories of the ion beam in the scanning range is shown by a one-dot chain line.

The beam parallelizing unit 34 aligns the traveling direction of an ion beam for scanning by the beam scan unit 32 substantially parallel to a trajectory of the designed beamline A. The beam parallelizing unit 34 includes a plurality of arc-shaped parallelizing lens electrodes in which an ion beam passing aperture is provided in a central portion in the y-direction. The parallelizing lens electrode is connected to a high-voltage power supply (not shown) and applies an electric field generated by a voltage applied to the ion beam to the ion beam to align the traveling direction of the ion beam substantially parallel to the beamline A. The beam parallelizing unit 34 may be replaced with another type of beam parallelizing device, for example, a magnet device that uses a magnetic field. In addition, an Accel/Decel (AD) column (not shown) for accelerating or decelerating the ion beam may be provided downstream of the beam parallelizing unit 34.

The angular energy filter (AEF) 36 analyzes energy of an ion beam and deflects ions having required energy downward (−y-direction) to guide ions to the implantation processing chamber 16. The angular energy filter 36 includes a pair of AEF electrodes for electric field deflection, which are connected to a high-voltage power supply (not shown). In FIG. 2, a positive voltage is applied to an AEF electrode on the upper side (+y side), and a negative voltage is applied to an AEF electrode on the lower side (−y side), so that an ion beam of positive charges is deflected downward (in a case of an ion beam of negative charges, a negative voltage is applied to the AEF electrode on the upper side, and a positive voltage is applied to the AEF electrode on the lower side). The angular energy filter 36 may be configured by a magnet device for deflection by a magnetic field or may be configured in combination with the pair of AEF electrodes for electric field deflection and the magnet device for deflection by a magnetic field.

As described above, the beamline unit 14 supplies, to the implantation processing chamber 16, an ion beam with which the wafer W, which is a workpiece, is to be irradiated. The implantation processing chamber 16 includes an energy defining slit 38, a plasma shower device 40, a side cup 42 (42L, 42R), a profiler cup 44, and the beam stopper 46, in order from the upstream side of the beamline A. As shown in FIG. 2, the implantation processing chamber 16 includes a platen driving device 50 that holds one or a plurality of wafers W.

The energy defining slit 38 is provided on the downstream side of the angular energy filter 36 and analyzes energy of an ion beam incident into the wafer W together with the angular energy filter 36. The energy defining slit 38 is an energy defining slit (EDS) configured by a horizontally long slit in the beam scanning direction (x-direction). The energy defining slit 38 allows an ion beam having energy within a desired value or a desired range to pass therethrough toward the wafer W and shields the other ion beams.

The plasma shower device 40 is disposed on the downstream side of the energy defining slit 38. The plasma shower device 40 supplies low-energy electrons to an ion beam and/or the surface (wafer surface to be processed) of the wafer W according to a beam current of the ion beam to suppress accumulation of positive charges on the wafer surface to be processed caused by ion implantation (so-called charge-up). For example, the plasma shower device 40 includes a shower tube through which the ion beam passes and a plasma generating device that supplies electrons into the shower tube.

The side cup 42 (42R, 42L) measures a beam current of an ion beam during ion implantation processing on the wafer W. As shown in FIG. 1, the side cups 42R and 42L are disposed to be deviated to the right and left (the x-direction) from the wafer W disposed on the beamline A and are disposed at positions that do not block the ion beam directed toward the wafer W during the ion implantation. The ion beam is used in scanning in the x-direction beyond a range where the wafer W is positioned. Accordingly, a part of the beam used in scanning is incident into the side cups 42R and 42L even during the ion implantation. In this manner, the beam current during the ion implantation processing is measured by the side cups 42R and 42L. Since the wafer W, which is a workpiece, is not irradiated with the ion beam incident into the side cups 42R and 42L during the ion implantation, the side cups 42R and 42L constitute a beam current measuring device that measures the beam current of the ion beam directed toward the irradiation-disabled direction in which the wafer W is not irradiated. A beam current measuring device such as a Faraday cup may be provided on the beam dump 26 with which the ion beam directed toward the irradiation-disabled direction collides.

The profiler cup 44 measures a beam current on the wafer surface to be processed. The profiler cup 44 is movable in the x-direction by an operation of a drive unit 45, is retreated from an implantation region where the wafer W is positioned during ion implantation and is inserted into the implantation region when the wafer W is not in the implantation region. The profiler cup 44 driven in the x-direction can measure the beam current over the entire beam scanning range in the x-direction. The profiler cup 44 may include a plurality of Faraday cups arrayed in the x-direction such that the beam current can be simultaneously measured at a plurality of positions in the beam scanning direction (x-direction). Since the ion beam incident into the profiler cup 44 is incident into the implantation region where the wafer W, which is a workpiece, is positioned during the ion implantation, the profiler cup 44 constitutes a beam current measuring device that measures the beam current of the ion beam toward the irradiation-enabled direction in which the wafer W can be irradiated. The beam current measuring device such as a Faraday cup may be provided on the beam stopper 46 with which the ion beam directed toward the irradiation-enabled direction collides.

At least one of the side cup 42 and the profiler cup 44 may include a single Faraday cup for measuring a beam current or may include an angle measurement device for measuring angle information of an ion beam. For example, the angle measurement device includes an aperture and a plurality of current detecting units provided to be separated away from the aperture in the beam traveling direction (z-direction). The angle measurement device can measure an angle component or an angle distribution of the beam in the aperture width direction by causing a plurality of current detecting units arranged in the aperture width direction to measure the ion beam, which has passed through the aperture. At least one of the side cup 42 and the profiler cup 44 may include a first angle measuring device that can measure angle information in the x-direction and/or a second angle measuring device that can measure angle information in the y-direction.

The platen driving device 50 includes the wafer holding device 52, a reciprocating mechanism 54, a twist angle control device 56, and a tilt angle control device 58.

The wafer holding device 52 for holding the wafer W to be irradiated with an ion beam includes an electrostatic chuck that is an electrostatic holding mechanism which constitutes a support mechanism supporting the wafer W and which holds the supported wafer W with electrostatic attraction. The wafer holding device 52 may include a temperature adjusting device for heating or cooling the wafer W to be subjected to ion implantation. The temperature adjusting device may be a heating device that heats the wafer W to a temperature higher than room temperature by 20° C. or more, 50° C. or more, or 100° C. or more or may be a cooling device that cools the wafer W to a temperature lower than room temperature by 20° C. or more, 50° C. or more, or 100° C. or more. The temperature of the wafer W affects a concentration distribution (implantation profile) of ions implanted into the wafer W and crystal defects (implantation damage) formed in the wafer W by the ion implantation. Processing of irradiating the wafer W having a temperature higher than room temperature with the ion beam is also called high-temperature implantation. In addition, processing of irradiating the wafer W having a temperature lower than room temperature with the ion beam is also called low-temperature implantation.

The reciprocating mechanism 54 is a drive mechanism that reciprocates the wafer holding device 52 including the support mechanism in a direction intersecting an ion beam. The reciprocating mechanism 54 reciprocates the wafer W held by the wafer holding device 52 in the y-direction by reciprocating the wafer holding device 52 including the support mechanism in the reciprocating direction (y-direction) perpendicular to the beam scanning direction (x-direction). In FIG. 2, a direction and a range of reciprocation of the wafer W are shown by an arrow Y.

The twist angle control device 56 constituting an implantation angle adjusting mechanism is a mechanism that controls a rotation angle (twist angle) of the wafer W disposed at the wafer holding device 52 and adjusts a twist angle between an alignment mark provided at an outer peripheral portion of the wafer W and a reference position by rotating the wafer W with a normal line perpendicular to the wafer surface to be processed at the center of the wafer surface to be processed as a rotation axis. Herein, the alignment mark of the wafer W is, for example, a notch or an orientation flat provided in the outer peripheral portion of the wafer W and is reference for a crystal direction of the wafer W or an angular position in a circumferential direction of the wafer W. The twist angle control device 56 is provided between the wafer holding device 52 and the reciprocating mechanism 54 and is reciprocated by the reciprocating mechanism 54 together with the wafer holding device 52.

The tilt angle control device 58 constituting the implantation angle adjusting mechanism is a mechanism that adjusts an inclination of the wafer W and adjusts a tilt angle between the traveling direction of an ion beam toward the wafer surface to be processed and the normal line of the wafer surface to be processed. In the example of FIG. 2, the tilt angle control device 58 adjusts, as a tilt angle, a rotation angle of which an axis in the x-direction, among inclination angles of the wafer W, is a center axis of rotation. The tilt angle control device 58 is provided between the reciprocating mechanism 54 and an inner wall of the implantation processing chamber 16 and adjusts the tilt angle of the wafer W by rotating the entire platen driving device 50 including the reciprocating mechanism 54 in an R-direction (FIG. 2).

The platen driving device 50 holds the wafer W such that the wafer W is movable between an ion implantation position where the wafer W is irradiated with an ion beam and a transport position where the wafer W is transported into or out of the wafer transport device 18. That is, the platen driving device 50 constitutes a moving device that moves the wafer holding device 52 between the ion implantation position where the wafer W supported by the wafer holding device 52 is irradiated with the ion beam and the transport position where the wafer transport device 18 can transport the wafer W between the wafer holding device 52 and the wafer transport device 18. FIG. 2 shows a state where the wafer W and the wafer holding device 52 are at the ion implantation position, and the wafer holding device 52 holds the wafer W to intersect with the beamline A. The transport position of the wafer W corresponds to the position of the wafer holding device 52 when a transport mechanism or a transport robot provided in the wafer transport device 18 transports the wafer W into or out of a transport port 48.

The beam stopper 46 is provided most downstream of the beamline A and is attached to, for example, the inner wall of the implantation processing chamber 16. An ion beam in a case where the wafer W and the profiler cup 44 are not present on the beamline A is incident into the beam stopper 46. The beam stopper 46 is disposed near the transport port 48 that connects the implantation processing chamber 16 and the wafer transport device 18 and is provided at a position vertically below (−y-direction) the transport port 48 in the example of FIG. 2.

The ion implanter 10 further includes a control device 60 that controls the entire operation thereof. The control device 60 is realized by cooperation of a hardware resource, such as a central processing unit, a memory, an input device, and an output device of a computer and a peripheral unit connected to the computer, and software executed using the hardware resource. Regardless of a type or an installation place of the computer, each function of the control device 60 may be realized by the hardware resource of a single computer or may be realized by combining the hardware resources distributed to a plurality of computers. Details of the control device 60 will be described later.

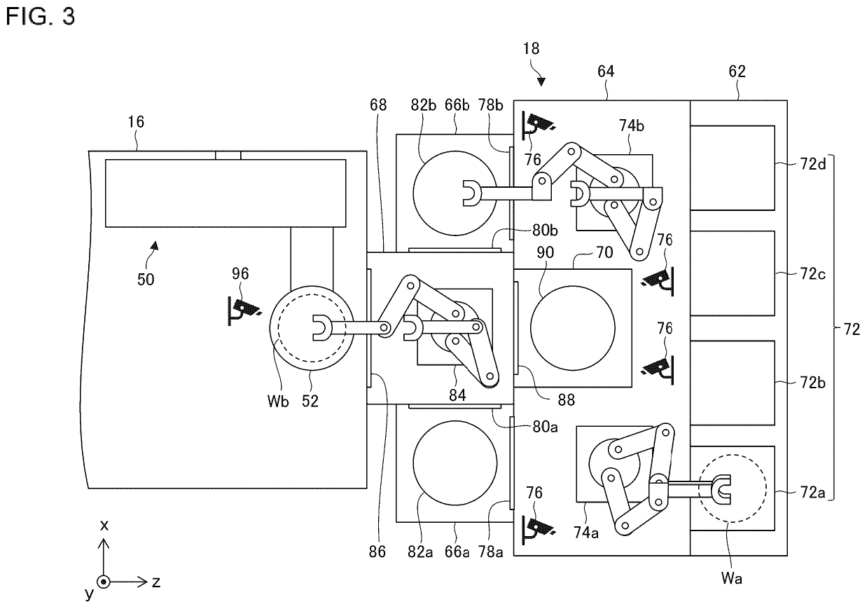

FIG. 3 is a top view showing a schematic configuration of the wafer transport device 18 that is the transport device which transports the wafer W (transports the wafer W into and out of) between the wafer holding device 52 and the wafer transport device 18. The wafer transport device 18 includes a load port 62, an atmospheric transport unit 64, a first load lock chamber 66a, a second load lock chamber 66b, an intermediate transport chamber 68, and a buffer chamber 70.

The load port 62 can receive a plurality of wafer containers 72a, 72b, 72c, and 72d (hereinafter, collectively referred to as a wafer container 72). The wafer transport device 18 transports an unprocessed wafer Wa of the wafer container 72 into the implantation processing chamber 16 and transports a processed wafer Wb on which ion implantation processing is performed in the implantation processing chamber 16 out to the wafer container 72.

In the shown state, the processed wafer Wb is in the implantation processing chamber 16 and is supported by the wafer holding device 52 in front of a processing chamber gate valve 86 corresponding to the transport port 48 of FIG. 2. In this state, the processed wafer Wb is transported from the wafer holding device 52 into the intermediate transport chamber 68 of the wafer transport device 18 by an intermediate transport mechanism 84 of the intermediate transport chamber 68. As described above, FIG. 3 shows a state where the wafer holding device 52 that supports the processed wafer Wb is at the transport position where the wafer can be transported between the wafer transport device 18 and the wafer holding device 52. On the other hand, when ion implantation processing is performed on the wafer in the implantation processing chamber 16, the platen driving device 50 moves the wafer, which is a processing target, together with the wafer holding device 52 from the transport position in FIG. 3 to the ion implantation position in FIG. 2.

The atmospheric transport unit 64 includes a first atmospheric transport mechanism 74a, a second atmospheric transport mechanism 74b, and one or a plurality of first imaging devices 76. The first atmospheric transport mechanism 74a is provided between the load port 62 and the first load lock chamber 66a. The first atmospheric transport mechanism 74a includes, for example, two robot arms for transporting the wafer. The first atmospheric transport mechanism 74a transports the wafer before the ion implantation processing from a first wafer container 72a or a second wafer container 72b into the atmospheric transport unit 64 and transports the wafer, on which ion implantation processing is performed, out of the atmospheric transport unit 64 to the first wafer container 72a or the second wafer container 72b. As will be described later, the first imaging device 76 images the wafer (the unprocessed wafer Wa and/or the processed wafer Wb) which is a processing target being transported in the atmospheric transport unit 64 and acquires first disposition information that can be used for alignment. The first atmospheric transport mechanism 74a transports the unprocessed wafer into the first load lock chamber 66a in a state of being associated with the first disposition information and transports the wafer, on which ion implantation processing is performed, out of the first load lock chamber 66a.

The second atmospheric transport mechanism 74b is provided between the load port 62 and the second load lock chamber 66b. The second atmospheric transport mechanism 74b includes, for example, two robot arms for transporting the wafer. The second atmospheric transport mechanism 74b transports the wafer before ion implantation processing from a third wafer container 72c or a fourth wafer container 72d into the atmospheric transport unit 64 and transports the wafer, on which ion implantation processing is performed, out of the atmospheric transport unit 64 to the third wafer container 72c or the fourth wafer container 72d. As will be described later, the first imaging device 76 images the wafer (the unprocessed wafer Wa and/or the processed wafer Wb) which is a processing target being transported in the atmospheric transport unit 64 and acquires first disposition information that can be used for alignment. The second atmospheric transport mechanism 74b transports the unprocessed wafer into the second load lock chamber 66b in a state of being associated with the first disposition information and transports the wafer, on which ion implantation processing is performed, out of the second load lock chamber 66b.

The first imaging device 76 is configured by one or a plurality of cameras or image sensors or the like positioned at any places in the atmospheric transport unit 64 in order to acquire the first disposition information for adjusting (aligning) a center position or a rotation position (rotation angle) of the wafer (the unprocessed wafer Wa and/or the processed wafer Wb), which is the processing target. The first imaging device 76 partially or entirely images the wafer, which is the processing target being transported in the atmospheric transport unit 64 one or a plurality of times and acquires one or a plurality of images that can be used for alignment of the wafer. Although details will be described later, in order to detect the rotation position of the wafer, which is the processing target, mainly, an alignment mark such as a notch and an orientation flat provided in a peripheral edge portion of the wafer is imaged by the first imaging device 76. In addition, in order to detect the center position of the wafer, which is the processing target, mainly, the peripheral edge portion and/or the entire contour or the outer shape of the wafer is imaged by the first imaging device 76.

In particular, since the unprocessed wafer Wa transported from the wafer container 72 into the atmospheric transport unit 64 does not necessarily have an aligned center position or an aligned rotation position, positioning (alignment) is performed using the first disposition information acquired by the first imaging device 76 before being held by the wafer holding device 52 in the implantation processing chamber 16. In the typical wafer transport device 18 in which an aligner for the alignment of the wafer is provided in the atmospheric transport unit 64, it is necessary to complete the alignment before the unprocessed wafer Wa is transported into the load lock chambers 66a and 66b. However, in the present embodiment in which such an aligner is not provided, as will be described later, the alignment may be performed when the wafer holding device 52 holds the unprocessed wafer Wa in the implantation processing chamber 16.

The first load lock chamber 66a and the second load lock chamber 66b are provided between the atmospheric transport unit 64 and the intermediate transport chamber 68, respectively. For example, the first load lock chamber 66a and the second load lock chamber 66b are adjacent to the atmospheric transport unit 64 in the z-direction and are adjacent to the intermediate transport chamber 68 in the x-direction. The intermediate transport chamber 68 is provided adjacent to the implantation processing chamber 16 in, for example, the z-direction. The buffer chamber 70 is provided adjacent to the intermediate transport chamber 68 in, for example, the z-direction.

The intermediate transport chamber 68 is maintained in a medium vacuum state of approximately 10⁻¹ Pa in a steady state. A vacuum pump (not shown) such as a turbo molecular pump is connected to the intermediate transport chamber 68. On the other hand, the atmospheric transport unit 64 is provided under the atmospheric pressure and transports the wafer in the atmospheric atmosphere. The first load lock chamber 66a and the second load lock chamber 66b are rooms or spaces partitioned to realize wafer transport between the intermediate transport chamber 68 maintained in the medium vacuum state and the atmospheric transport unit 64 under the atmospheric pressure. The first load lock chamber 66a and the second load lock chamber 66b can be evacuated and opened to the atmosphere, respectively, during wafer transport. A roughing pump such as an oil rotary vacuum pump and a dry vacuum pump is connected in order to evacuate the first load lock chamber 66a and the second load lock chamber 66b.

The first load lock chamber 66a includes a first atmospheric-side gate valve 78a provided between the atmospheric transport unit 64 and the first load lock chamber 66a, a first intermediate gate valve 80a provided between the intermediate transport chamber 68 and the first load lock chamber 66a, and a first temperature adjusting device 82a. Similarly, the second load lock chamber 66b includes a second atmospheric-side gate valve 78b provided between the second load lock chamber 66b and the atmospheric transport unit 64, a second intermediate gate valve 80b provided between the second load lock chamber 66b and the intermediate transport chamber 68, and a second temperature adjusting device 82b.

In a case where the first load lock chamber 66a is evacuated or opened to the atmosphere, the first atmospheric-side gate valve 78a and the first intermediate gate valve 80a are closed. In a case where the wafer is transported between the atmospheric transport unit 64 and the first load lock chamber 66a, the first atmospheric-side gate valve 78a is opened in a state where the first intermediate gate valve 80a is closed. In a case where the wafer is transported between the intermediate transport chamber 68 and the first load lock chamber 66a, the first intermediate gate valve 80a is opened in a state where the first atmospheric-side gate valve 78a is closed.

Similarly, in a case where the second load lock chamber 66b is evacuated or opened to the atmosphere, a second atmospheric-side gate valve 78b and a second intermediate gate valve 80b are closed. In a case where the wafer is transported between the atmospheric transport unit 64 and the second load lock chamber 66b, the second atmospheric-side gate valve 78b is opened in a state where the second intermediate gate valve 80b is closed. In a case where the wafer is transported between the intermediate transport chamber 68 and the second load lock chamber 66b, the second intermediate gate valve 80b is opened in a state where the second atmospheric-side gate valve 78b is closed.

The first temperature adjusting device 82a heats or cools the wafer transported into the first load lock chamber 66a to adjust a wafer temperature. The first temperature adjusting device 82a may heat or cool the wafer before ion implantation processing to adjust the wafer temperature suitable for the ion implantation processing. The first temperature adjusting device 82a may cool or heat the wafer on which the ion implantation processing is performed to adjust the temperature to room temperature or a temperature close to room temperature.

The second temperature adjusting device 82b heats or cools the wafer transported into the second load lock chamber 66b to adjust the wafer temperature. The second temperature adjusting device 82b may heat or cool the wafer before ion implantation processing to adjust the wafer temperature suitable for the ion implantation processing. The second temperature adjusting device 82b may cool or heat the wafer on which the ion implantation processing is performed to adjust the temperature to room temperature or a temperature close to room temperature.

The intermediate transport chamber 68 includes the intermediate transport mechanism 84. The intermediate transport mechanism 84 includes, for example, two robot arms for transporting the wafer. The intermediate transport mechanism 84 transports the wafer between the intermediate transport chamber 68 and a room adjacent thereto. The intermediate transport mechanism 84 transports the wafer before ion implantation processing from the first load lock chamber 66a and transports the wafer on which the ion implantation processing is performed out to the first load lock chamber 66a. The intermediate transport mechanism 84 transports the wafer before ion implantation processing from the second load lock chamber 66b and transports the wafer on which the ion implantation processing is performed out to the second load lock chamber 66b. The intermediate transport mechanism 84 transports the wafer before the ion implantation processing into the implantation processing chamber 16 and transports the wafer on which the ion implantation processing is performed out of the implantation processing chamber 16. The intermediate transport mechanism 84 transports the wafer before the ion implantation processing or the wafer on which the ion implantation processing is performed into the buffer chamber 70 and transports the wafer before the ion implantation processing or the wafer on which the ion implantation processing is performed out of the buffer chamber 70.

The processing chamber gate valve 86 is provided between the implantation processing chamber 16 and the intermediate transport chamber 68. The processing chamber gate valve 86 is opened in a case where the wafer is transported between the implantation processing chamber 16 and the intermediate transport chamber 68. The processing chamber gate valve 86 is closed in a case where the ion implantation processing is performed on the wafer in the implantation processing chamber 16.

A second imaging device 96 that images the wafer disposed on the wafer holding device 52 is provided in the implantation processing chamber 16. The second imaging device 96 is configured by one or a plurality of cameras or image sensors or the like provided in order to acquire second disposition information for alignment of the center position or the rotation position of the wafer, which is the processing target, as in the first imaging device 76 described above. Although details will be described later, the center position and/or the rotation position of the unprocessed wafer Wa disposed at the wafer holding device 52 is finally adjusted based on the first disposition information obtained from the first imaging device 76 and/or the second disposition information obtained from the second imaging device 96. The final adjustment of the rotation position of the unprocessed wafer Wa is performed by the twist angle control device 56 described above. The final adjustment of the center position of the unprocessed wafer Wa may be performed by the intermediate transport mechanism 84 (robot arm) and/or the reciprocating mechanism 54 described above. The second imaging device 96 may be provided not only in the implantation processing chamber 16 but also in the intermediate transport chamber 68, the buffer chamber 70, and the load lock chambers 66a and 66b.

The buffer chamber 70 is a room that temporarily stores the wafer that has been transported into the intermediate transport chamber 68. The buffer chamber 70 includes a buffer chamber gate valve 88 and a third temperature adjusting device 90. The buffer chamber gate valve 88 provided between the intermediate transport chamber 68 and the buffer chamber 70 is opened in a case where the wafer is transported between the intermediate transport chamber 68 and the buffer chamber 70 and is closed in a case where the third temperature adjusting device 90 adjusts the wafer temperature in the buffer chamber 70. The buffer chamber 70 may be omitted depending on the configuration of the ion implanter.

The third temperature adjusting device 90 heats or cools the wafer transported into the buffer chamber 70 to adjust the temperature of the wafer. The third temperature adjusting device 90 may heat or cool the wafer before ion implantation processing to adjust the wafer temperature suitable for the ion implantation processing. The third temperature adjusting device 90 may cool or heat the wafer on which the ion implantation processing is performed to adjust the temperature to room temperature or a temperature close to room temperature. The first temperature adjusting device 82a, the second temperature adjusting device 82b, and the third temperature adjusting device 90 may not actively adjust the temperature of the wafer, and the temperature adjusting devices 82a, 82b, and 90 may be configured as mere wafer holders.

Although an example of the wafer transport device 18 is shown in FIG. 3, the present invention can be applied to any other type of transport device. For example, the present invention can also be applied to a wafer transport device including a rotating arm as shown in the related art.

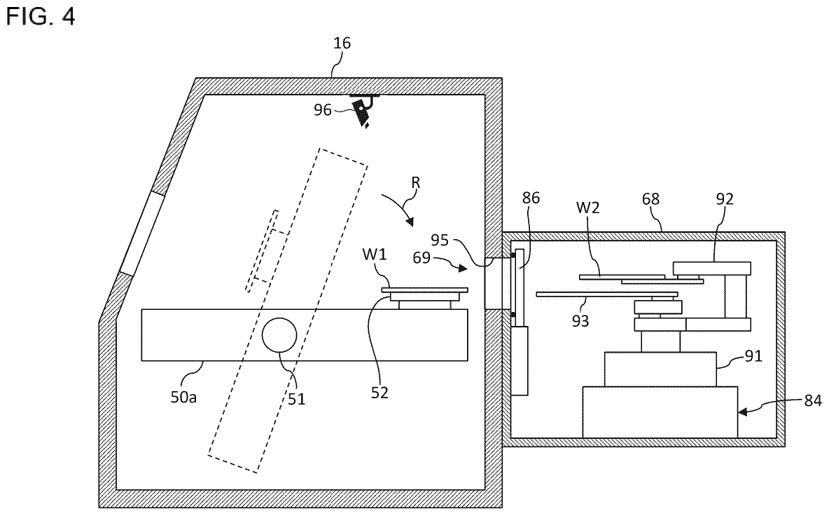

FIGS. 4 to 7 are views schematically showing a swap operation by the intermediate transport mechanism 84. FIG. 4 shows a state before wafer replacement by the intermediate transport mechanism 84. A moving device 50a of the platen driving device 50 rotates about a rotation axis 51 in a direction of an arrow R from the ion implantation position shown by a dotted line to the transport position shown by a solid line, so that a first wafer W1 on which ion implantation processing is performed in the implantation processing chamber 16 can be transported out. A intermediate transport chamber-implantation processing chamber communication mechanism 69 between the implantation processing chamber 16 and the intermediate transport chamber 68 is provided with a communication port 95 connecting the implantation processing chamber 16 and the intermediate transport chamber 68 and the processing chamber gate valve 86 blocking the communication port 95. A second wafer W2 before the ion implantation processing is held by an upper arm 92 of the intermediate transport mechanism 84 in the intermediate transport chamber 68.

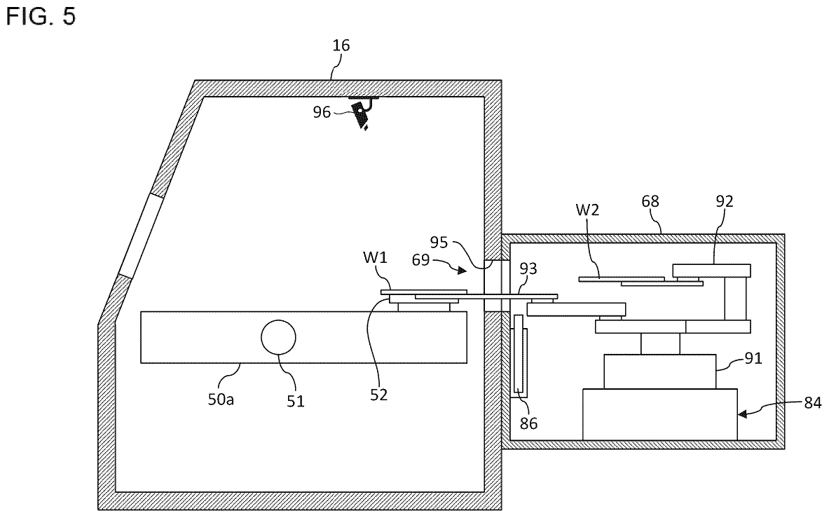

FIG. 5 shows a state where the first wafer W1 is held by the intermediate transport mechanism 84. When the processing chamber gate valve 86 is opened and the implantation processing chamber 16 and the intermediate transport chamber 68 communicate with each other, a lower arm 93 of the intermediate transport mechanism 84 extends toward the implantation processing chamber 16, and the first wafer W1 is held by a holding unit at a tip of the lower arm 93.

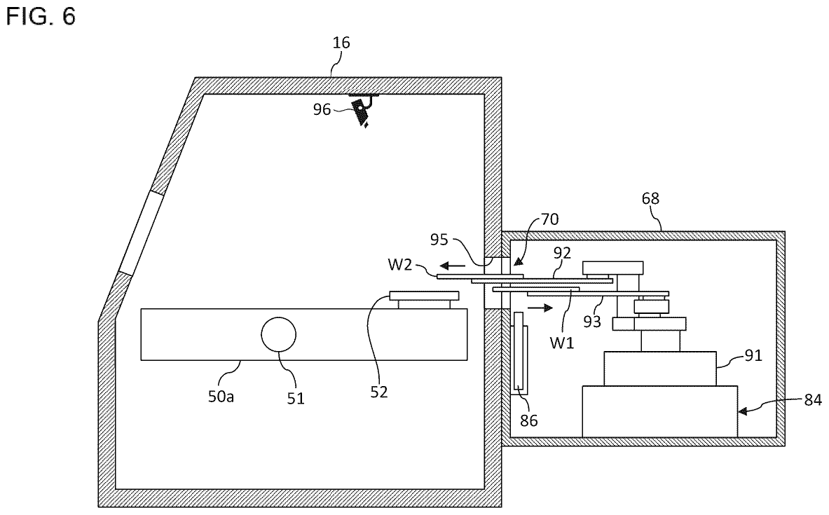

FIG. 6 shows a state where the first wafer W1 and the second wafer W2 are swapped by the intermediate transport mechanism 84. The intermediate transport mechanism 84 contracts the lower arm 93 to an intermediate transport chamber 68 side to transport the first wafer W1 out to the intermediate transport chamber 68 from the implantation processing chamber 16 and extends the upper arm 92 to an implantation processing chamber 16 side to transport the second wafer W2 from the intermediate transport chamber 68 into the implantation processing chamber 16. In this case, a swap operation in which the first wafer W1 and the second wafer W2 pass each other is realized in a positional relationship where the second wafer W2 is on the upper side and the first wafer W1 is on the lower side.

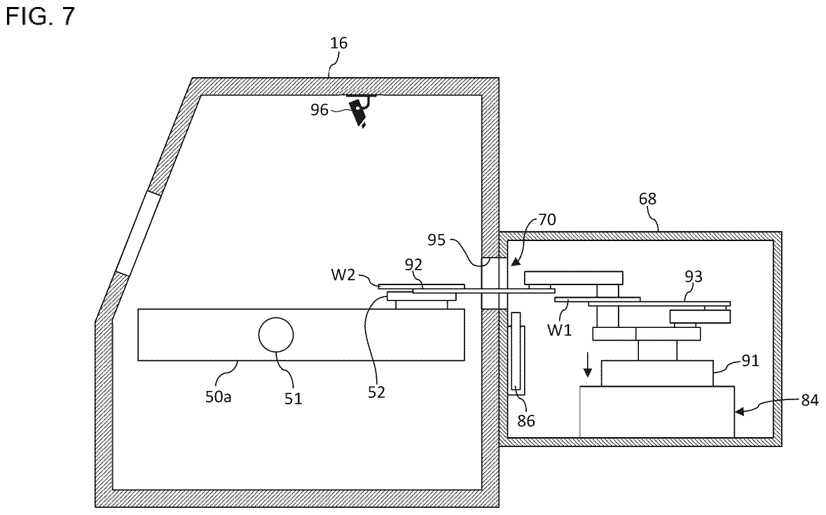

FIG. 7 shows a state where the second wafer W2 is placed on the wafer holding device 52 of the moving device 50a by the intermediate transport mechanism 84. The intermediate transport mechanism 84 accommodates the first wafer W1 in the intermediate transport chamber 68 by contracting the lower arm 93, and lowers an intermediate transport main body 91 to lower the positions of the upper arm 92 and the lower arm 93 after extending the upper arm 92 to a placing position (transport position) of the second wafer W2. After the second wafer W2 is placed on the wafer holding device 52, the upper arm 92 is contracted to close the processing chamber gate valve 86, thereby completing replacement between the first wafer W1 and the second wafer W2.

The second wafer W2 newly transported into the implantation processing chamber 16 in this manner is imaged by the second imaging device 96 described above, and the center position and/or the rotation position are finally adjusted. For example, the upper arm 92 that transports the second wafer W2 into the implantation processing chamber 16 finally adjusts the center position of the second wafer W2 on the wafer holding device 52 based on the second disposition information obtained from the second imaging device 96 and/or the first disposition information obtained from the first imaging device 76. In addition, the twist angle control device 56 (FIG. 2) provided in the wafer holding device 52 finally adjusts the rotation position (twist angle) of the second wafer W2 on the wafer holding device 52 based on the second disposition information obtained from the second imaging device 96 and/or the first disposition information obtained from the first imaging device 76. After such alignment is completed, the moving device 50a rotates about the rotation axis 51 from the transport position to an ion implantation start position, and ion implantation with respect to the second wafer W2 is started.

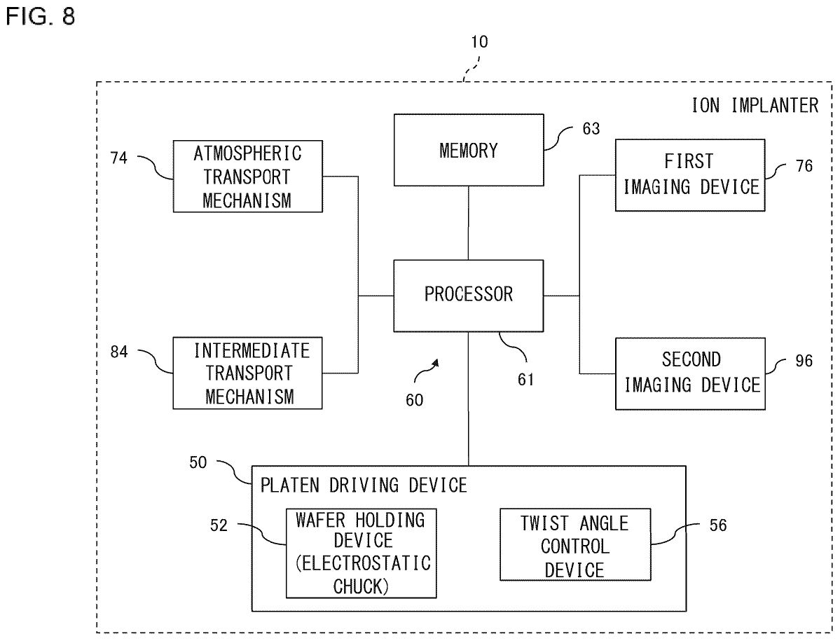

FIG. 8 is a functional block diagram of the ion implanter 10 related to alignment of the wafer. The control device 60 of the ion implanter 10 includes a processor 61 and a memory 63. The processor 61 controls each of the units of the ion implanter 10 including an atmospheric transport mechanism 74 (74a, 74b), the intermediate transport mechanism 84, the first imaging device 76, the second imaging device 96, and the platen driving device 50. The memory 63 stores a program that can be executed by the processor 61. The processor 61 controls each of the units of the ion implanter 10 based on the program stored in the memory 63.

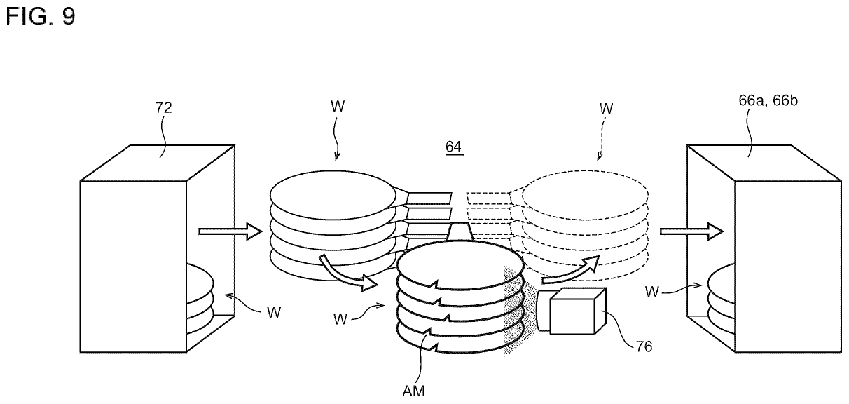

FIG. 9 schematically shows an example in which the first imaging device 76 simultaneously images a plurality of wafers W for alignment of the wafer according to the present embodiment. In this example, for example, five wafers W constituting one batch are collectively taken out from the wafer container 72 in which the plurality of wafers W are stored by the atmospheric transport mechanisms 74a and 74b (not shown). The one batch is configured by 2 to 25 wafers W, is preferably configured by 5 to 13 wafers W, and is more preferably configured by 6 or 7 wafers W.

In FIG. 9, one or the plurality of first imaging devices 76, only one of which is schematically shown, image a wafer group W being transported by the atmospheric transport mechanisms 74a and 74b (wafer transport device 18). In particular, the first imaging device 76 images an alignment mark AM such as a notch that is important for the alignment of each wafer W. As schematically shown in FIG. 9, the rotation positions of the alignment marks AM of the plurality of wafers W in one batch can be different from each other. For this reason, in a general aligner that uses light passing through the notch up and down, it is difficult to collectively measure the alignment marks of a plurality of wafers (even if light can pass through the notch of one wafer, there is a high probability in which the light is blocked by a non-notch portion of another wafer).

On the other hand, in the present embodiment, the first imaging device 76 typically images a mainly peripheral edge portion of the wafer group W once or a plurality of times from the side of the wafer group W. As a result, all the alignment marks AM of the plurality of wafers W in one batch are imaged in one or a plurality of images. In this manner, the present embodiment including the first imaging device 76 is suitable for transport and alignment measurement of the plurality of wafers W in the atmospheric transport unit 64. However, the present invention is also applicable to the transport and the alignment measurement of one wafer W.

The wafer group W for which alignment measurement is performed by the first imaging device 76 while being transported in the atmospheric transport unit 64 by the atmospheric transport mechanisms 74a and 74b is transported to the load lock chambers 66a and 66b.

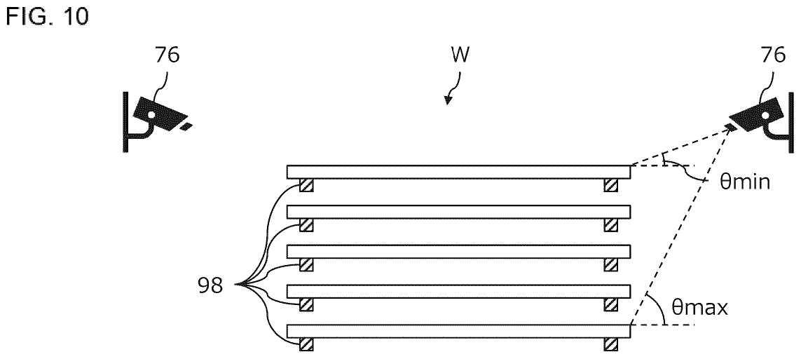

FIG. 10 schematically shows the wafer group W imaged by the first imaging device 76 in side view. For example, the five wafers W constituting one batch are placed on a wafer placing portion 98 with a predetermined gap in the up-down direction at an imaging position for the first imaging device 76. Herein, the gap of each wafer W in the up-down direction is set such that the arm of the atmospheric transport mechanisms 74a and 74b or the intermediate transport mechanism 84 for supporting and transporting each wafer W can be inserted. The wafer placing portion 98, on which the wafer W is placed, outside the implantation processing chamber 16 may be a part of the atmospheric transport mechanisms 74a and 74b that transport the wafer group W, may be a part of a wafer container in which the wafer transported by the atmospheric transport mechanisms 74a and 74b is stored, or may be a part of a wafer container that is disposed on a conveyance path by the atmospheric transport mechanisms 74a and 74b and in which the wafer group W is temporarily stored for imaging.

At one or a plurality of any imaging positions on the conveyance path for the atmospheric transport mechanisms 74a and 74b, one or the plurality of first imaging devices 76 simultaneously image the plurality of the wafers W placed on the wafer placing portion 98 from the side. It is preferable that the first imaging devices 76 collectively image the peripheral edge portions of the plurality of wafers W from diagonally above and/or diagonally below.

In the shown example in which the first imaging device 76 images the wafer group W from diagonally above (the side and upward), an imaging angle θmin for the uppermost wafer W is the smallest, and an imaging angle θmax for the lowermost wafer W is the largest. Herein, the imaging angle represents an angle at which a straight line connecting the first imaging device 76 and the closest peripheral edge portion of the wafer W which is an imaging target forms a horizontal plane (the surface of the wafer W). The minimum imaging angle θmin is preferably 10 degrees or more and more preferably 30 degrees or more so that the first imaging device 76 can appropriately image the peripheral edge portion of each wafer W. It is preferable that the maximum imaging angle θmax is 80 degrees or less and more preferably 45 degrees or less. Each first imaging device 76 disposed so that an appropriate imaging angle is realized for each wafer W in this manner can simultaneously image the peripheral edge portions of the plurality of (five in the shown example) wafers W.

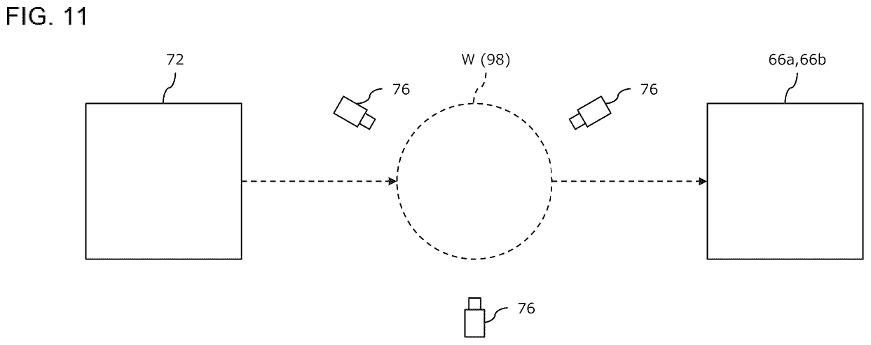

In addition, in order to efficiently perform alignment measurement (imaging for alignment) of the wafer group W, it is preferable that the plurality of cameras 76 (first imaging devices 76) simultaneously image different locations in the peripheral edge portions of the plurality of wafers W. FIG. 11 schematically shows a disposition example of the plurality of cameras 76 around one wafer placing portion 98 (an imaging position for the camera 76) on the conveyance path for the atmospheric transport mechanisms 74a and 74b between the wafer container 72 and the load lock chambers 66a and 66b in top view. It is preferable that the plurality of cameras 76 are provided at three or more different positions around the wafer placing portion 98 at substantially equal intervals. In the shown example in which three cameras 76 are provided, each of the cameras 76 is provided with equal intervals of 120 degrees in the circumferential direction with respect to a center of the wafer placing portion 98 and/or the wafer W.

It is preferable that such a plurality of cameras 76 image partially overlapping regions in the peripheral edge portion of the wafer group W. In the shown example, each of the cameras 76 images a region or a range larger than ⅓ of the peripheral edge portion or the outer peripheral portion of the wafer group W. By the overlapping imaging by such a plurality of cameras 76, the entire peripheral edge portion of the wafer group W is imaged over a plurality of images. As will be described later, the processor 61 can reproduce or recognize the entire contour or the outer shape of the peripheral edge portion of the wafer group W and/or each wafer W by composing the plurality of images.

In the example of FIG. 11, different locations in the peripheral edge portion of one or the plurality of wafers W being transported by the atmospheric transport mechanisms 74a and 74b are imaged by the plurality of cameras 76. However, different locations in the peripheral edge portion of the one or the plurality of wafers W being transported by the atmospheric transport mechanisms 74a and 74b may be imaged by one camera 76.

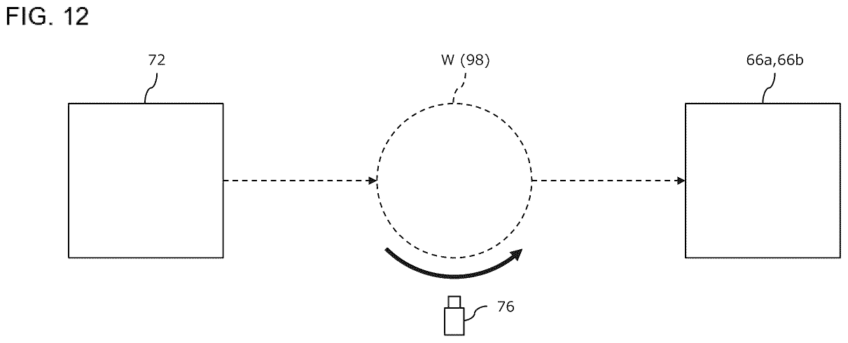

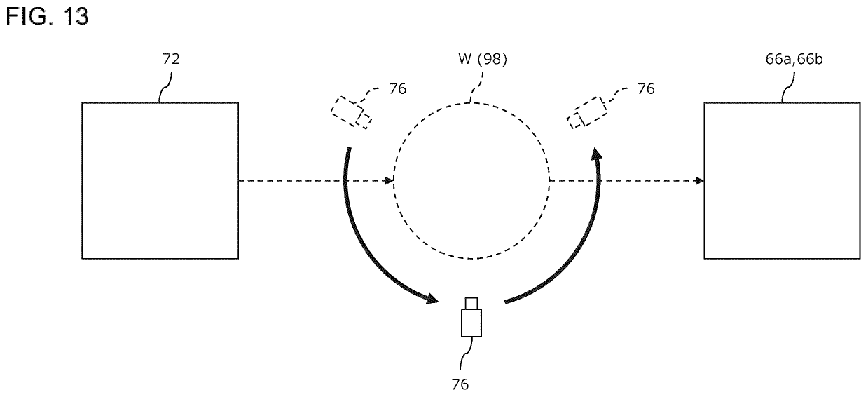

For example, as schematically shown in FIG. 12, as the wafer group W placed on the wafer placing portion 98 is rotationally driven by the atmospheric transport mechanisms 74a and 74b or the like, substantially the entire peripheral edge portion of the wafer group W may be continuously imaged by passing through an imaging range of one camera 76. In addition, as schematically shown in FIG. 13, while one camera 76 is moved relative to the one or the plurality of wafers W, different locations in the peripheral edge portion of the wafer W may be imaged. In the shown example, as one camera 76 images the wafer W while sequentially moving to three positions where the three cameras 76 are provided in FIG. 11, the substantially entire image of the peripheral edge portion of the wafer W can be imaged.

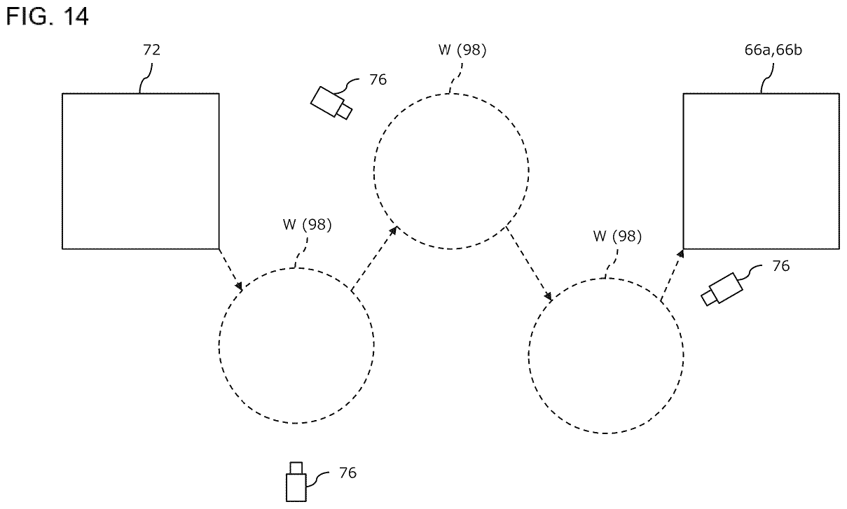

In addition, as schematically shown in FIG. 14, a plurality of the wafer placing portions 98 (at least one imaging position for the camera 76) may be provided on the conveyance path for the atmospheric transport mechanisms 74a and 74b. At least one camera 76 that sequentially image different locations in the peripheral edge portion of the wafer W transported by the atmospheric transport mechanisms 74a and 74b is provided around each wafer placing portion 98. In the shown example, one camera 76 is provided around each of the three wafer placing portions 98 to which the wafer W is sequentially transported by the atmospheric transport mechanisms 74a and 74b. Each of the cameras 76 corresponds to each of the cameras 76 provided in FIG. 11 and images substantially the same location in the peripheral edge portion of the wafer W. For this reason, even with the configuration of FIG. 14, substantially the entire image of the peripheral edge portion of the wafer W being transported can be imaged as in FIGS. 11 to 13. One camera 76 that is movable relative to the three wafer placing portions 98 may be configured to image substantially the entire image of the peripheral edge portion of the wafer W placed on the three wafer placing portions 98.

Next, an example of a program (stored in one or the plurality of memories 63) that can be executed by one or the plurality of processors 61 shown in FIG. 8 in the ion implanter 10 having the configuration described above is shown by a flowchart. For the purpose of simplifying description, a plurality of flowcharts are shown individually for convenience. However, processing of a part or all of the flowcharts is combined in any order insofar as they do not hinder each other. In addition, “S” in the flowcharts means a step or processing.

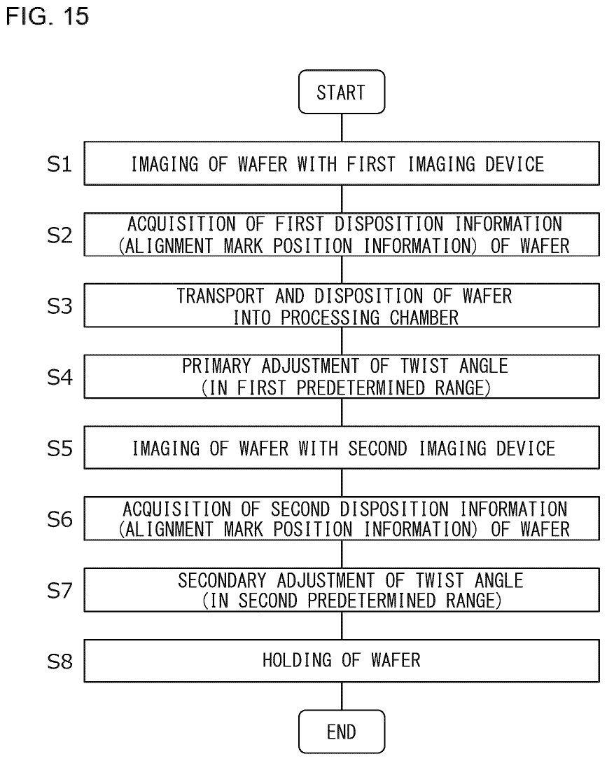

FIG. 15 is an example of a program for aligning the rotation position of the one or the plurality of wafers W (specifically, the unprocessed wafers Wa), which are processing targets. In S1, (a) the first imaging device 76 images each wafer W. As shown with FIGS. 9 to 14, in the step of (a), the program may cause the one or the plurality of first imaging devices 76 to mainly simultaneously or continuously image substantially the entire peripheral edge portion of the one or the plurality of wafers W placed on the one or the plurality of wafer placing portions 98 during atmospheric transport by the atmospheric transport mechanisms 74a and 74b.

In S2, (b) the first disposition information of each wafer W is acquired based on the image captured by the first imaging device 76 in S1. The first disposition information herein includes position information of each alignment mark AM such as a notch and an orientation flat in the peripheral edge portion of each wafer W. In S1, since substantially the entire peripheral edge portion of each wafer W is imaged by the first imaging device 76, each alignment mark AM in the peripheral edge portion of each wafer W can be detected in S2.

In S3, (c) each wafer W is transported to the implantation processing chamber 16 in a state of being associated with the first disposition information acquired in S2 by the wafer transport device 18 (specifically, the atmospheric transport mechanisms 74a and 74b and the intermediate transport mechanism 84) and is disposed at the wafer holding device 52. In particular, in the step of (c), as also shown in FIGS. 4 to 7, the intermediate transport mechanism 84 transports one wafer W from the plurality of wafers W transported by the atmospheric transport mechanisms 74a and 74b to the implantation processing chamber 16 and disposes the wafer W at the wafer holding device 52.

In S4, (d-1) the twist angle control device 56 adjusts the twist angle of the wafer W such that the alignment mark AM of the wafer W disposed at the wafer holding device 52 in S3 enters a first predetermined range, based on the first disposition information acquired in S2 and associated with the wafer W in S3. Herein, the first predetermined range is an imaging range of the second imaging device 96 that images the alignment mark AM in subsequent S5. That is, the second imaging device 96 can reliably image the alignment mark AM in S5 through such primary adjustment of the twist angle.

In S5, (e) after the step of (d-1), the alignment mark AM at the peripheral edge portion of the wafer W disposed at the wafer holding device 52 is imaged by the second imaging device 96. In S6, (f) the alignment mark AM is detected based on the image captured by the second imaging device 96 in the step of (e), and the second disposition information of the wafer W is acquired based on the detected alignment mark AM. The second disposition information herein is position information of the alignment mark AM of the wafer W, as in the first disposition information acquired in S2.

In S7, (g) the twist angle control device 56 adjusts the twist angle of the wafer W such that the alignment mark AM enters a second predetermined range based on the second disposition information acquired in S6. Herein, the second predetermined range overlaps the first predetermined range (the imaging range of the second imaging device 96) in S4 and is narrower than the first predetermined range. Therefore, through such secondary adjustment (final adjustment) of the twist angle, the rotation position of the wafer W is determined more accurate than in the primary adjustment in S4. In S8, the electrostatic chuck in the wafer holding device 52 holds the wafer W for which the alignment is completed in S7 with electrostatic attraction. As the wafer W held in S8 is rotated together with the wafer holding device 52 in a direction opposite to the arrow R in FIG. 4, the wafer W is moved to the ion implantation position shown by a dotted line, so that ion implantation processing is performed. S8 may be performed immediately after the wafer W is disposed at the wafer holding device 52 in S3.

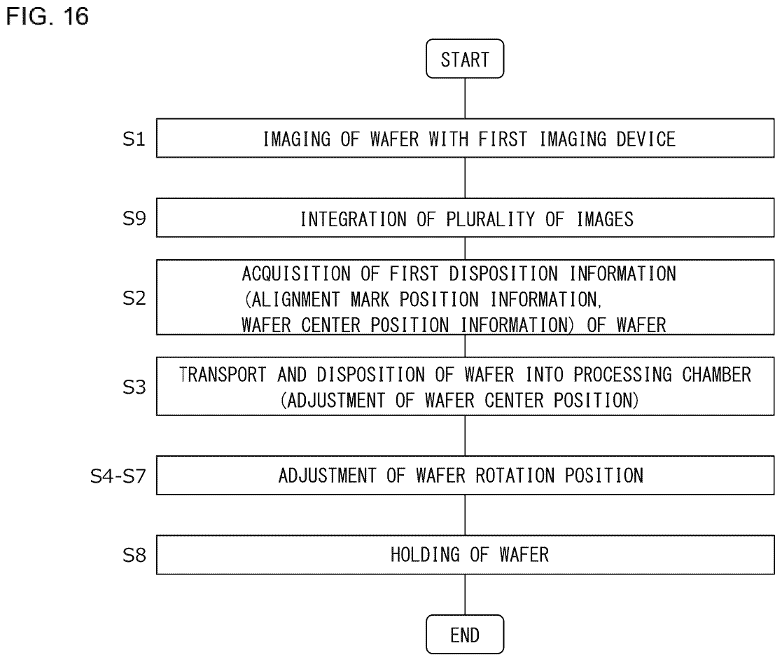

FIG. 16 is an example of a program for aligning the center position of the one or the plurality of wafers W (specifically, the unprocessed wafers Wa), which are processing targets. The same steps or processing will be assigned with the same reference numerals as those in the flowchart described above, and redundant description thereof will be omitted.

In S1, (a) the first imaging device 76 images each wafer W. In S9, in the step of (a), the first imaging device 76 may image different locations of each wafer W, acquire a plurality of images, and integrate the plurality of images. The processor 61 can reproduce or recognize, for example, the entire contour or the entire outer shape of the peripheral edge portion of each wafer W by composing the plurality of images in S9.

In S2, (b) the first disposition information of each wafer W is acquired based on the image captured by the first imaging device 76 in S1. The first disposition information herein includes position information of the center of each wafer W. In the step of (b), the first disposition information (alignment mark position information, wafer center position information) may be acquired based on the image integrated in S9. In the step of (b), position information of the center of each wafer W may be calculated as a part of the first disposition information based on the plurality of images captured in S1. In the step of (b), the first disposition information (alignment mark position information, wafer center position information) may be acquired with reference to a device pattern on each wafer W included in the images captured by the first imaging device 76 in S1.

In S3, (c) each wafer W is transported by the wafer transport device 18 to the implantation processing chamber 16 in a state of being associated with the first disposition information acquired in S2 and is disposed at the wafer holding device 52. In particular, in S3, (d-2) based on the first disposition information (wafer center position information) acquired in S2, the wafer transport device 18 (in particular, the intermediate transport mechanism 84) adjusts the position of the wafer W such that the center of each wafer W disposed at the wafer holding device 52 enters a predetermined range.

Next, as described above with reference to FIG. 15, alignment processing S4 to S7 of the rotation position of the wafer W is performed. In S8, the electrostatic chuck in the wafer holding device 52 holds the wafer W, of which the alignment of the center position in S3 and the alignment of the rotation position in S7 are completed, with electrostatic attraction. As the wafer W held in S8 is rotated together with the wafer holding device 52 in the direction opposite to the arrow R in FIG. 4, the wafer W is moved to the ion implantation position shown by the dotted line, so that ion implantation processing is performed. S8 may be performed immediately after the wafer W is disposed at the wafer holding device 52 in S3.

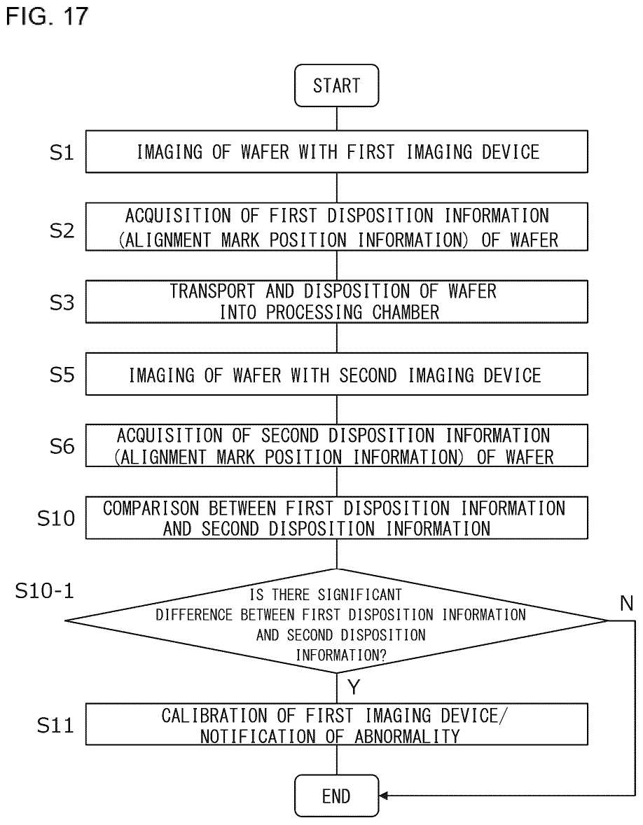

FIG. 17 is an example of a program for calibration or notification using the first imaging device 76 and the second imaging device 96. The same steps or processing will be assigned with the same reference numerals as those in the flowchart described above, and redundant description thereof will be omitted.

In S1, (a) the first imaging device 76 images each wafer W. In S2, (b) the first disposition information of each wafer W is acquired based on the image captured by the first imaging device 76 in S1. The first disposition information herein includes position information of each alignment mark AM such as a notch and an orientation flat in the peripheral edge portion of each wafer W. In S3, (c) each wafer W is transported by the wafer transport device 18 to the implantation processing chamber 16 in a state of being associated with the first disposition information acquired in S2 and is disposed at the wafer holding device 52.

In S5, (e′) the alignment mark AM at the peripheral edge portion of the wafer W disposed at the wafer holding device 52 is imaged by the second imaging device 96. In S6, (j) the alignment mark AM (second disposition information) of the wafer W is detected based on the image captured by the second imaging device 96 in the step of (e′). In S10, the first disposition information acquired in S2 and the second disposition information acquired in S6 are compared with each other.

In S11, in a case where there is a significant difference between the first disposition information and the second disposition information as a result of the comparison in S10 (for example, in a case where there is a deviation larger than a predetermined threshold) (Y in S10-1), the first imaging device 76 may be calibrated according to the difference between (k) the position of the alignment mark AM detected by the step of (b) (S2) and the position of the alignment mark AM detected by the step of (j) (S6). Typically, the second imaging device 96 that images the wafer W in the implantation processing chamber 16 is considered to have higher measurement accuracy and reliability than the first imaging device 76 that images the wafer W in the wafer transport device 18. Therefore, in a case where there is a deviation in the position of the alignment mark AM imaged by both imaging devices 76 and 96, it is preferable to calibrate the first imaging device such that the measurement result of the second imaging device 96 is set as reference, and the measurement result of the first imaging device 76 approaches the measurement result of the second imaging device 96.

In addition, in S11, in a case where there is a significant difference between the first disposition information and the second disposition information as a result of the comparison in S10 (for example, in a case where there is a deviation larger than a predetermined threshold) (Y in S10-1), a notification in which the difference between (l) the position of the alignment mark AM detected by the step of (b) (S2) and the position of the alignment mark AM detected by the step of (j) (S6) is out of a predetermined allowable range may be made. In a case where there is a deviation exceeding the allowable range in the position of the alignment mark AM imaged by both imaging devices 76 and 96, there is a possibility in which the rotation position of the wafer W, which is a processing target, cannot be appropriately adjusted. Therefore, the purpose is to quickly notify a manager or the like of the ion implanter 10 of the fact and to prompt an urgent inspection or the like.

Unlike in FIG. 17, various types of processing such as calibration and diagnosis can be performed only by the first imaging device 76 without using the second imaging device 96. For example, (h) the reference wafer W of which the alignment mark AM has a known position may be imaged by the first imaging device 76, and the first imaging device 76 may be calibrated according to a difference between the detected position of the alignment mark AM of the reference wafer W and the known position. In addition, (i) the reference wafer W of which the alignment mark AM has a known position may be imaged by the first imaging device 76, and the wafer transport device 18 (in particular, the atmospheric transport mechanisms 74a and 74b) and/or the first imaging device 76 may be diagnosed for the presence or absence of an abnormality according to a difference between the detected position of the alignment mark AM of the reference wafer W and the known position. In addition, the presence or absence of the abnormality in each of the first imaging devices 76 may be diagnosed by (m) detecting each disposition of the wafer W in each image captured by the first imaging device 76 in step of (a) (S1) and (n) comparing each detected disposition of the wafer W.

The present invention has been described hereinbefore based on the embodiment. It is clear for those skilled in the art that the embodiment is an example, various modification examples are possible for a combination of each component and each processing process, and such modification examples are also within the scope of the present invention.

In the present embodiment, the ion implanter 10 has been given as an example. However, the present invention is not limited to the ion implanter 10 and can be applied to any wafer processing device that performs any processing on the wafer. Examples of the wafer processing device include various types of semiconductor manufacturing devices such as an exposure device, a heat treatment device, an ashing device, a sputtering device, a dicing device, an inspection device, and a cleaning device. Such a wafer processing device includes at least the first imaging device 76 that images the wafer W, which is a processing target, a processing chamber (the implantation processing chamber 16 in the ion implanter 10) that provides a space for processing the wafer W, the processing chamber including the wafer holding device 52 configured to hold the wafer W inside the processing chamber, the wafer transport device 18 that transports the wafer W to the processing chamber and that disposes the wafer W at the wafer holding device 52, the one or the plurality of processors 61, and the one or the plurality of memories 63 in which a program executable by the one or the plurality of processors 61 is stored.

A functional configuration of each device described in the embodiment can be realized by a hardware resource or a software resource or by cooperation of the hardware resource and the software resource. A processor, a ROM, a RAM, or other LSI can be used as the hardware resource. A program such as an operating system and an application can be used as the software resource.

The present invention relates to the wafer processing device and the like.

It should be understood that the invention is not limited to the above-described embodiment, but may be modified into various forms on the basis of the spirit of the invention. Additionally, the modifications are included in the scope of the invention.

What is claimed is:

1. A wafer processing device comprising:
a first imaging device that images a wafer which is a processing target;
a processing chamber that provides a space for processing the wafer and that includes a wafer holding device configured to hold the wafer inside the processing chamber;
a wafer transport device that transports the wafer into the processing chamber and that disposes the wafer on the wafer holding device;
one or a plurality of processors; and
one or a plurality of memories in which a program executable by the one or the plurality of processors is stored,
wherein the program includes the following steps of (a) to (c):
(a) imaging the wafer with the first imaging device,
(b) acquiring first disposition information of the wafer based on a captured image, and
(c) transporting the wafer into the processing chamber and disposing the wafer on the wafer holding device with the wafer transport device in a state of being associated with the first disposition information.

2. The wafer processing device according to claim 1, further comprising:
a twist angle control device that controls a twist angle of the wafer disposed on the wafer holding device,
wherein the first disposition information includes position information of an alignment mark of the wafer, and the program includes the following step of (d-1):
(d-1) adjusting the twist angle of the wafer such that the alignment mark of the wafer disposed on the wafer holding device enters a first predetermined range based on the first disposition information with the twist angle control device.

3. The wafer processing device according to claim 1,
wherein the first disposition information includes position information of a center of the wafer, and
the program includes the following step of (d-2):
(d-2) adjusting a position of the wafer such that the center of the wafer disposed on the wafer holding device enters a predetermined range based on the first disposition information with the wafer transport device.

4. The wafer processing device according to claim 2, further comprising:
a second imaging device that images the wafer disposed on the wafer holding device,
wherein the program includes the following steps of (e) to (g):
(e) after the step of (d-1), imaging the wafer disposed on the wafer holding device with the second imaging device,
(f) detecting the alignment mark based on an image captured in the step of (e) and acquiring second disposition information of the wafer based on the detected alignment mark, and
(g) adjusting the twist angle of the wafer such that the alignment mark enters a second predetermined range based on the second disposition information with the twist angle control device.

5. The wafer processing device according to claim 4,
wherein the second predetermined range overlaps the first predetermined range, and the second predetermined range is narrower than the first predetermined range.

6. The wafer processing device according to claim 5,
wherein the first predetermined range is an imaging range of the second imaging device.

7. The wafer processing device according to claim 1,
wherein the program
causes the first imaging device to image different locations of the wafer, acquires a plurality of images, and integrates the plurality of images in the step of (a), and
acquires the first disposition information based on the integrated images in the step of (b).

8. The wafer processing device according to claim 7,
wherein the program
calculates position information of a center of the wafer as a part of the first disposition information based on the plurality of images in the step of (b).

9. The wafer processing device according to claim 1, further comprising:
a wafer placing portion, on which the wafer is placed, outside the processing chamber,
wherein the program causes the first imaging device to image the wafer placed on the wafer placing portion in the step of (a).

10. The wafer processing device according to claim 9,
wherein a plurality of the wafers are placed on the wafer placing portion with a predetermined gap, and
the program
causes the first imaging device to collectively image peripheral edge portions of the plurality of wafers placed on the wafer placing portion in the step of (a), and
detects each of alignment marks in the peripheral edge portions of the wafers based on the image captured by the first imaging device in the step of (b).

11. The wafer processing device according to claim 10,
wherein the first imaging device includes a plurality of cameras provided at different positions around the wafer placing portion, and
the program causes the plurality of cameras to image different locations in the peripheral edge portions of the plurality of wafers in the step of (a).

12. The wafer processing device according to claim 11,
wherein the plurality of cameras are provided at three or more different positions around the wafer placing portion.

13. The wafer processing device according to claim 12,
wherein the plurality of cameras are provided with substantially equal intervals around the wafer placing portion.

14. The wafer processing device according to claim 12,
wherein the program causes the plurality of cameras to image partially overlapping regions in the peripheral edge portions of the wafers in the step of (a).

15. The wafer processing device according to claim 11,
wherein the program causes the plurality of cameras to simultaneously image the different locations in the peripheral edge portions of the plurality of wafers in the step of (a).

16. The wafer processing device according to claim 10,
wherein the program causes the wafer transport device to transport one wafer, among the plurality of wafers, into the processing chamber and to dispose the wafer on the wafer holding device in the step of (c).

17. The wafer processing device according to claim 10,
wherein the program causes the first imaging device to image the peripheral edge portions of the plurality of wafers from diagonally above and/or diagonally below in the step of (a).

18. The wafer processing device according to claim 17,
wherein the program causes the first imaging device to image the peripheral edge portions of the plurality of wafers in a direction of forming an angle between 10 degrees and 80 degrees with respect to a horizontal plane in the step of (a).

19. The wafer processing device according to claim 18,
wherein the program causes the first imaging device to image the peripheral edge portions of the plurality of wafers in a direction of forming an angle between 30 degrees and 45 degrees with respect to the horizontal plane in the step of (a).

20. The wafer processing device according to claim 11,
wherein a plurality of the wafer placing portions are provided, and one or more cameras of the first imaging device are provided at each of two or more wafer placing portions, among the plurality of wafer placing portions, and
the program causes the cameras to image different locations in the peripheral edge portions of the wafers in the step of (a).

21. The wafer processing device according to claim 1,
wherein the program causes the first imaging device to image the wafer being transported by the wafer transport device in the step of (a).

22. The wafer processing device according to claim 1,
wherein the program causes the first imaging device to image different locations of the wafer being transported by the wafer transport device in the step of (a).

23. The wafer processing device according to claim 1,
wherein the program causes the first imaging device to image different locations of the wafer while relatively moving the first imaging device with respect to the wafer in the step of (a).

24. The wafer processing device according to claim 1,
wherein the program acquires the first disposition information with reference to a device pattern included in the image captured by the first imaging device in the step of (b).

25. The wafer processing device according to claim 1,
wherein the program includes the following step of (h):
(h) causing the first imaging device to image a reference wafer of which an alignment mark has a known position and calibrating the first imaging device according to a difference between a detected position of the alignment mark of the reference wafer and the known position.

26. The wafer processing device according to claim 1,
wherein the program includes the following step of (i):
(i) causing the first imaging device to image a reference wafer of which an alignment mark has a known position and diagnosing the wafer transport device and/or the first imaging device according to a difference between a detected position of the alignment mark of the reference wafer and the known position.

27. The wafer processing device according to claim 1, further comprising:
a second imaging device that images the wafer disposed on the wafer holding device,
wherein the program includes the following steps of (e′), (j), and (k):
(e′) imaging the wafer disposed on the wafer holding device with the second imaging device,
(j) detecting an alignment mark based on an image captured by the second imaging device, and
(k) calibrating the first imaging device according to a difference between a position of the alignment mark detected in the step of (b) and a position of the alignment mark detected in the step of (j).

28. The wafer processing device according to claim 1, further comprising:
a second imaging device that images the wafer disposed on the wafer holding device,
wherein the program includes the following steps of (e′), (j), and (l):
(e′) imaging the wafer disposed on the wafer holding device with the second imaging device,
(j) detecting an alignment mark based on an image captured by the second imaging device, and
(l) making a notification in which a difference between a position of the alignment mark detected in the step of (b) and a position of the alignment mark detected in the step of (j) is out of a predetermined allowable range.

29. The wafer processing device according to claim 7,
wherein the program includes the following steps of (m) and (n):
(m) detecting each disposition of the wafer for each of the images captured by the first imaging device in the step of (a), and
(n) comparing each detected disposition of the wafer.

30. A wafer processing method in a wafer processing device including
a first imaging device that images a wafer which is a processing target,
a processing chamber that provides a space for processing the wafer and that includes a wafer holding device configured to hold the wafer inside the processing chamber, and
a wafer transport device that transports the wafer into the processing chamber and that disposes the wafer on the wafer holding device,
the wafer processing method comprising:
(a) a step of imaging the wafer with the first imaging device;
(b) a step of acquiring first disposition information of the wafer based on a captured image; and
(c) a step of transporting the wafer into the processing chamber and disposing the wafer on the wafer holding device with the wafer transport device in a state of being associated with the first disposition information.

31. An ion implanter comprising:
a first imaging device that images a wafer which is an ion implantation processing target;
a processing chamber that provides a space for performing ion implantation processing on the wafer and that includes a wafer holding device configured to hold the wafer inside the processing chamber;
a wafer transport device that transports the wafer into the processing chamber and that disposes the wafer on the wafer holding device;
one or a plurality of processors; and
one or a plurality of memories in which a program executable by the one or the plurality of processors is stored,
wherein the program includes the following steps of (a) to (c):
(a) imaging the wafer with the first imaging device,
(b) acquiring first disposition information of the wafer based on a captured image, and
(c) transporting the wafer into the processing chamber and disposing the wafer on the wafer holding device with the wafer transport device in a state of being associated with the first disposition information.
